(19) United States
(12) Patent Application Publication
(10) Pub. No.: US 2024/0387478 A1
(43) Pub. Date: Nov. 21, 2024

(54) Light Emitting Display Apparatus

(71) Applicant: LG Display Co, Ltd., Seoul (KR)

(72) Inventors: Daehee Kim, Paju-Si (KR); MoonSoo Kim, Paju-si (KR)

(21) Appl. No.: 18/649,409

(22) Filed: Apr. 29, 2024

(30) Foreign Application Priority Data
May 17, 2023 (KR) 10-2023-0063684

(51) Int. Cl. H01L 25/075; H01L 25/16; H01L 27/12; H01L 33/56

(52) U.S. Cl. CPC H01L 25/0753; H01L 25/167; H01L 27/124; H01L 33/56

(57) ABSTRACT

A light emitting display apparatus includes a substrate including a display area and a non-display area, a light emitting layer provided in a pixel in the display area, a cathode on the light emitting layer, and an auxiliary electrode connected to the cathode through a contact hole in the pixel, and a fluorine-based protective layer that covers an upper surface, a lower surface, and a side surface of a contact-area light emitting layer that is in the contact hole.

### CROSS-REFERENCE TO RELATED APPLICATION

This application claims the benefit of Republic of Korea Patent Application No. 10-2023-0063684 filed on May 17, 2023, which is hereby incorporated by reference in its entirety.

### BACKGROUND

### Field of Technology

The present disclosure relates to a light emitting display apparatus.

### Discussion of the Related Art

Light emitting display apparatuses are mounted on or provided in electronic products such as televisions, monitors, notebook computers, smart phones, tablet computers, electronic pads, wearable devices, watch phones, portable information devices, navigation devices, or vehicle control display devices, etc., to display images.

As a size of a light emitting display panel progressively increases, a need for uniform cathode voltages to be supplied to all areas of the cathode is increasing.

### SUMMARY

Accordingly, the present disclosure is directed to providing a light emitting display apparatus that substantially obviates one or more problems due to limitations and disadvantages of the related art.

An embodiment of the present disclosure is directed to providing a light emitting display apparatus in which a light emitting layer provided in a contact hole where a cathode and an auxiliary electrode are connected is wrapped by a fluorine-based protective layer.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these and other advantages and in accordance with the purpose of the disclosure, as embodied and broadly described herein, there is provided a light emitting display apparatus comprising: a substrate including a display area and a non-display area; a light emitting layer in a pixel in the display area; a cathode on the light emitting layer; an auxiliary electrode connected to the cathode through a contact hole in the pixel; and a fluorine-based protective layer that covers an upper surface, a lower surface that is opposite the upper surface, and a side surface that is between the upper surface and the lower surface of a contact-area light emitting layer that is in the contact hole.

In one embodiment, a display device comprises: a substrate including a display area having a light emission area and a non-light emission area; a transistor in the light emission area; an auxiliary electrode in the non-light emission area; a planarization layer on the transistor and the auxiliary electrode, the planarization layer including a contact hole through a portion of the planarization layer in the non-light emission area; an anode electrode in the light emission area, the anode electrode connected to the transistor; a light emission layer on the anode electrode in the light emission area, the light emission layer including a portion that extends into the contact hole that is in the non-light emission area; a cathode electrode on the light emission layer in the light emission area and electrically connected to the auxiliary electrode, the cathode electrode including a portion that extends into the contact hole in the non-light emission area; and a moisture blocking layer in the non-light emission area, the moisture blocking layer wrapping around the portion of the light emission layer in the contact hole.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is an exemplary diagram illustrating a configuration of a light emitting display apparatus according to an embodiment of the present disclosure;

FIG. 2 is an exemplary diagram illustrating a structure of a pixel applied to a light emitting display apparatus according to an embodiment of the present disclosure;

FIG. 3 is an exemplary diagram illustrating a structure of a control driver applied to a light emitting display apparatus according to an embodiment of the present disclosure;

FIG. 4 is a plan view illustrating pixels arranged in an area A of FIG. 1 according to an embodiment of the present disclosure;

FIG. 5 is an exemplary diagram illustrating a cross-sectional surface taken along line K-K′ illustrated in FIG. 4 according to an embodiment of the present disclosure;

FIGS. 6A, 6B, 6C, and FIG. 6D are exemplary diagrams illustrating a structure in which a metal layer and cathode illustrated in FIG. 5 are connected according to an embodiment of the present disclosure;

FIGS. 7 and 8 are exemplary diagrams illustrating a method of connecting the metal layer and cathode illustrated in FIG. 5 according to an embodiment of the present disclosure; and

FIGS. 9A, 9B, 9C, 9D, 9E, 9F, and 9g are exemplary diagrams illustrating a method of manufacturing a light emitting display panel according to an embodiment of the present disclosure.

### DETAILED DESCRIPTION

Reference will now be made in detail to the exemplary embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. When “comprise,” “have,” and “include” described in the present specification are used, another part may be added unless “only” is used. The terms of a singular form may include plural forms unless referred to the contrary.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct(ly)” is used.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first,” “second,” “A,” “B,” “(a),” “(b),” etc. may be used. These terms are intended to identify the corresponding elements from the other elements, and basis, order, or number of the corresponding elements should not be limited by these terms. The expression that an element is “connected,” “coupled,” or “adhered” to another element or layer the element or layer can not only be directly connected or adhered to another element or layer, but also be indirectly connected or adhered to another element or layer with one or more intervening elements or layers “disposed,” or “interposed” between the elements or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in co-dependent relationship.

Hereinafter, embodiments of the present disclosure will be described in detail with reference to the accompanying drawings.

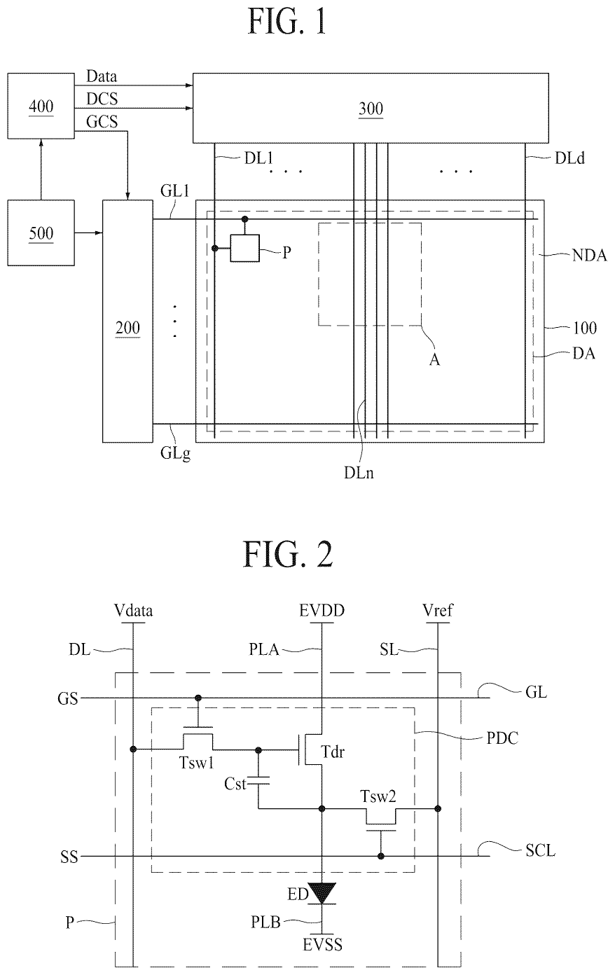

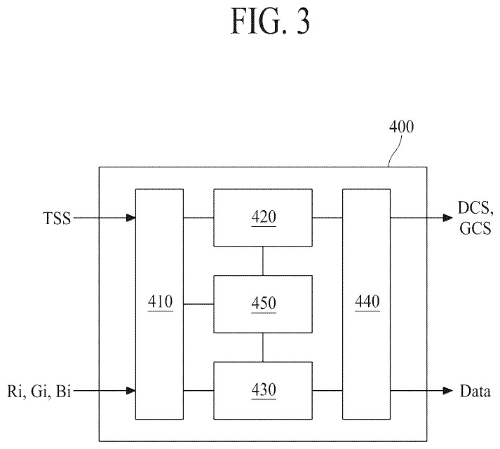

FIG. 1 is an exemplary diagram illustrating a configuration of a light emitting display apparatus according to an embodiment of the present disclosure, FIG. 2 is an exemplary diagram illustrating a structure of a pixel applied to a light emitting display apparatus according to an embodiment of the present disclosure, and FIG. 3 is an exemplary diagram illustrating a structure of a control driver applied to a light emitting display apparatus according to an embodiment of the present disclosure.

A light emitting display apparatus according to an embodiment of the present disclosure can be various kinds of electronic devices or be included in various kinds of electronic devices. For example, the electronic device can be a smartphone, a tablet PC, a television, a monitor, etc., and the electronic device can be included in a smartphone, a tablet PC, a television, a monitor, etc.

The light emitting display apparatus according to an embodiment of the present disclosure, as illustrated in FIG. 1, can include a light emitting display panel 100 which includes a display area DA displaying an image and a non-display area NDA provided outside the display area DA, a gate driver 200 which supplies gate signals to a plurality of gate lines GL1 to GLg provided in the display area DA of the display panel 100, a data driver 300 which supplies data voltages Vdata to a plurality of data lines DL1 to DLd provided in the display area DA of the display panel 100, a control driver 400 which controls driving of the gate driver 200 and the data driver 300, and a power supply 500 which supplies power to the control driver 400, the gate driver 200, the data driver 300, and the light emitting display panel 100.

The light emitting display panel 100 can include a display area DA and a non-display area NDA. Gate lines GL1 to GLg, data lines DL1 to DLd, and pixels P can be provided in the display area DA. Accordingly, an image can be output in the display area DA. Here, g and d are natural numbers.

The non-display area NDA can be provided to surround the outside of the display area DA and can also be provided inside the display area DA. An image is not displayed in the non-display area NDA.

For example, when a camera hole is provided in the display area DA, a non-display area NDA in which an image is not displayed can be provided in the camera hole and around the camera hole.

The pixel P included in the light emitting display panel 100, as illustrated in FIG. 2, can include a pixel driving circuit PDC which includes a switching transistor Tsw1, a storage capacitor Cst, a driving transistor Tdr, and a sensing transistor Tsw2, and a light emitting device ED connected to the pixel driving circuit PDC.

A first terminal of the driving transistor Tdr can be connected to a first voltage supply line through which a first voltage EVDD is supplied, and a second terminal of the driving transistor Tdr can be connected to the light emitting device ED.

A first terminal of the switching transistor Tsw1 can be connected to a data line DL, a second terminal of the switching transistor Tsw1 can be connected to a gate of the driving transistor Tdr, and a gate of the switching transistor Tsw1 can be connected to a gate line GL.

A data voltage Vdata can be supplied through the data line DL and a gate signal GS can be supplied through the gate line GL.

The sensing transistor Tsw2 can be provided for measuring a threshold voltage of the driving transistor Tdr or mobility of an electrical charge. A first terminal of the sensing transistor Tsw2 can be connected to the second terminal of the driving transistor Tdr and the light emitting device ED, a second terminal of the sensing transistor Tsw2 can be connected to a sensing line SL through which the reference voltage Vref is supplied, and a gate of the sensing transistor Tsw2 can be connected to a sensing control line SCL through which a sensing control signal SCS is supplied.

The sensing line SL can be connected to the data driver 300 and can be connected to the power supply 500 through the data driver 300. For example, the reference voltage Vref supplied from the power supply 500 can be supplied to the pixels through the sensing line SL and sensing signals transmitted from the pixels P can be processed by the data driver 300.

The light emitting device ED can include a first electrode supplied with a first voltage EVDD through the driving transistor Tdr, a second electrode connected to a second voltage supply line PLB through which a second voltage is supplied, and a light emitting layer provided between the first electrode and the second electrode. The first electrode can be an anode and the second electrode can be a cathode.

The structure of the pixel P applied to the present disclosure is not limited to the structure illustrated in FIG. 2. Accordingly, the structure of the pixel P can be changed to various shapes.

The gate driver 200 can be configured as an integrated circuit (IC) and mounted in the non-display area NDA. Moreover, the gate driver 200 can be directly embedded into the non-display area NDA by using a gate-in panel (GIP) type. When the gate driver 200 uses the GIP type, transistors configuring the gate driver 200 can be provided in the non-display area NDA through the same process as transistors included in the pixels P of the display area DA. Moreover, the gate driver 200 can be provided in the display area DA in which light emitting devices are provided.

The gate driver 200 can supply gate pulses GP1 to GPg to the gate lines GL1 to GLg.

When a gate pulse GP generated by the gate driver 200 is supplied to a gate of the switching transistor Tsw1 included in the pixel P, the switching transistor Tsw1 can be turned on. When the switching transistor Tsw1 is turned on, data voltage Vdata supplied through a data line DL can be supplied to the pixel P.

When a gate-off signal generated by the gate driver 200 is supplied to the switching transistor Tsw1, the switching transistor Tsw1 can be turned off. When the switching transistor Tsw1 is turned off, a data voltage may not be supplied to the pixel P any longer.

The gate signal GS supplied to the gate line GL can include the gate pulse GP and the gate-off signal.

The power supply 500 can generate various powers and supply the generated powers to the control driver 400, the gate driver 200, the data driver 300, and the light emitting display panel 100.

The data driver 300 can be connected to data lines DL1 to DLd and sensing lines SL. For example, each of the sensing lines can be commonly connected to pixels included in a unit pixel capable of displaying white among pixels connected to one gate line, but can be connected to each of the pixels configuring the unit pixel.

The data driver 300 can output data voltages Vdata by using data control signals DCS and image data Data transmitted from the control driver 400.

The control driver 400 can realign input image data Ri, Gi, and Bi transmitted from an external system by using a timing synchronization signal TSS transmitted from the external system and can generate a data control signal DCS which is to be supplied to the data driver 300 and a gate control signal GCS which is to be supplied to the gate driver 200.

To this end, as illustrated in FIG. 3, the control driver 400 can include a data aligner 430 (e.g., a circuit) which realigns input image data Ri, Gi, and Bi to generate image data Data and supply the image data Data to the data driver 300, a control signal generator 420 (e.g., a circuit) which generates the gate control signal GCS and the data control signal DCS by using the timing synchronization signal TSS, a control unit 410 (e.g., a circuit) which transmits the timing synchronization signal TSS transmitted from the external system to the control signal generator 420 and transmits the input image data Ri, Gi, and Bi transmitted from the external system to the data aligner 430, and an output unit 440 (e.g., a circuit) which supplies the data driver 300 with the image data Data generated by the data aligner 430 and the data control signal DCS generated by the control signal generator 420 and supplies the gate driver 200 with the gate control signal GCS generated by the control signal generator 420.

The control signal generator 420 can generate a power control signal supplied to the power supply 500.

The control driver 400 can further include a storage unit for storing various information. The storage unit 450 can be included in the control driver 400 as illustrated in FIG. 3, but can be separated from the control driver 400 and provided independently.

The external system can perform a function of driving the control driver 400 and an electronic device. For example, when the electronic device is a television (TV), the external system can receive various kinds of sound information, image information, letter information, etc., over a communication network and can transmit the received image information to the control driver 400. In this case, the image information can be input image data Ri, Gi, and Bi.

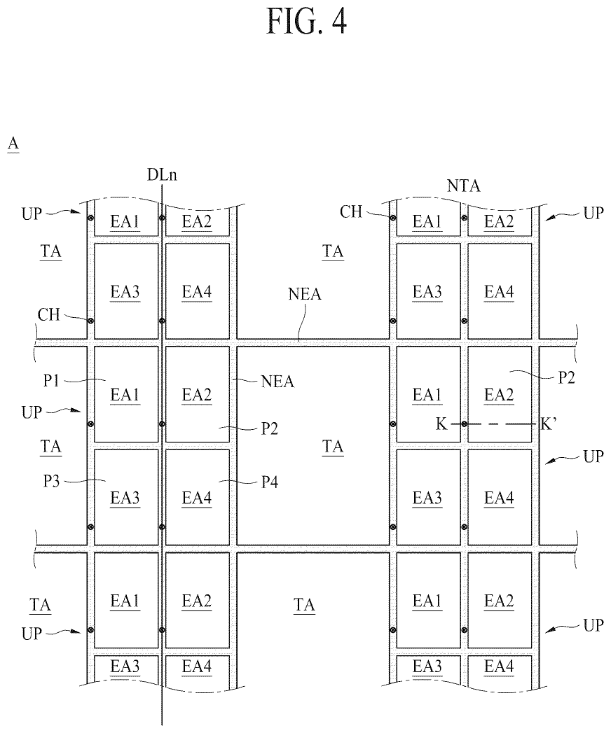

FIG. 4 is a plan view illustrating pixels arranged in an area A of FIG. 1 according to one embodiment.

The present disclosure can be applied to a light emitting display panel 100 which includes a transmission area TA, and can also be applied to a light emitting display panel 100 which does not include a transmission area TA.

Hereinafter, for convenience of description, a light emitting display panel 100 including the transmission area TA will be described as an example of a light emitting display panel according to the present disclosure.

The display area DA can include a transmission area TA (or referred to as a transparent area) and a non-transmission area NTA. The transmission area TA can be an area which allows most of light incident from the outside to pass through. The non-transmission area NTA can be an area which does not transmit most of light incident from the outside. Thus, the transmission area TA transmits more external light tan the non-transmission area NTA. Moreover, the non-transmission area NTA is an area where pixels P are provided and the transmission area TA is an area without any pixels P.

Due to the transmission area TA, an object or background located on the rear side of a light emitting display panel 100 can be visible from the front of the light emitting display panel 100.

The non-transmission area NTA can be disposed between adjacent transmission areas TA, and pixels P and signal lines can be disposed in the non-transmission area NTA.

Particularly, the non-transmission area NTA can include a light emission area EA in which light is emitted and a non-light emission area NEA in which light is not emitted.

Light can be emitted by a light emitting device ED in a light emission area EA of the non-transmission area NTA, and a pixel driving circuit configuring a pixel P and signal lines connected to the pixel can be provided in the non-light emission area NEA of the non-transmission area NTA.

Moreover, a bank surrounding the light emission area EA can be provided in the non-light emission area NEA.

The signal lines can include first signal lines extending in a first direction (or Y-axis direction) in the non-transmission area NTA and second signal lines extending in a second direction (or X-axis direction) different from the first direction. For example, the first signal lines can include data lines DL and sensing lines SL, and the second signal lines can include gate lines GL.

A unit pixel UP including at least three pixels P can be provided in the non-transmission area NTA. White light can be emitted through the unit pixel UP. Hereinafter, for convenience of description, a light emitting display apparatus according to an embodiment of the present disclosure will be described using a unit pixel UP including four pixels P1, P2, P3, and P4 as an example.

The unit pixel UP can include a first pixel P1, a second pixel P2, a third pixel P3, and a fourth pixel P4. The first pixel P1 can include a first light emission area EA1 which emits light of a first color, the second pixel P2 can include a second light emission area EA2 which emits light of a second color, the third pixel P3 can include a third light emission area EA3 which emits light of a third color, and the fourth pixel P4 can include a fourth light emission area EA4 which emits light of a fourth color.

For example, the first light emission area EA1 can emit blue light, the second light emission area EA2 can emit red light, the third light emission area EA3 can emit green light, and the fourth light emission area EA4 can emit white light.

However, in addition to the combination of pixels emitting the colors described above, the unit pixel UP can also be configured to include a combination of pixels emitting other colors. For example, the four pixels P1, P2, P3, and P4 can emit blue light, red light, green light, and white light as described above, but the present disclosure is not limited thereto. Accordingly, the four pixels P1, P2, P3, and P4 can emit another combination of color lights.

The transmission area TA can be disposed between adjacent non-transmission areas NTA, and light emitting devices ED and pixel driving circuits PDC configuring the pixels P1, P2, P3, and P4 may not be provided in the transmission area TA.

For example, non-transmission element or opaque element may not be disposed in the transmission area TA, and thus, the transmission area TA can be an area with a high light transmittance.

For example, the transmission area TA may not overlap the pixel driving circuits PDC configuring the pixels P1, P2, P3, and P4. Moreover, the transmission area TA may not overlap light emitting devices configuring the pixels P1, P2, P3, and P4.

For example, the transmission area TA can be alternately arranged with the non-transmission area NTA along the first direction (or Y-axis direction) as illustrated in FIG. 4, and can be alternately arranged with the non-transmission area NTA along the second direction (or X-axis direction).

As another example, the transmission area TA can be arranged to surround the non-transmission area NTA, or the non-transmission area NTA can be arranged to surround the transmission area TA.

In the following description, when it is not required to differentiate the four pixels P1, P2, P3, and P4 configuring the unit pixel UP, each of the four pixels can be referred to as a pixel P.

Each of the pixels P can be provided with a color filter. A color of light emitted from each pixel P can be determined by a color of the color filter.

A transmission area TA can be provided on the left or right side of the four pixels P1, P2, P3, and P4 provided in the unit pixel UP.

For example, on the left side of the first pixels P1 and the third pixels P3 provided on the left side of an nth data line DLn provided in the substrate 101, a transmission area TA (for example, a first transmission area) through which light transmits can be provided. Moreover, on the right side of the second pixels P2 and the fourth pixels P4 provided on the right side of the nth data line DLn, a transmission area TA (for example, a second transmission area) through which light transmits can be provided.

A light emitting device ED can be provided in each of the light emission areas EA1, EA2, EA3, and EA4. The light emitting device ED can include an anode supplied with a first voltage EVDD through the driving transistor Tdr, a cathode connected to a second voltage supply line PLB through which a second voltage is supplied, and a light emitting layer provided between the anode and the cathode.

As a size of a light emitting display panel 100 progressively increases, a need for uniform cathode voltages to be supplied to all areas of the cathode is increasing. Accordingly, a light emitting display panel can be provided with an auxiliary electrode connected to the cathode. The auxiliary electrode is connected to an auxiliary line, and the auxiliary line can be connected to the power supply 500.

The auxiliary electrode line can be included in the signal lines. Accordingly, the auxiliary electrode line can extend from the non-transmission area NTA to the first direction (or Y-axis direction) or the second direction (or X-axis direction).

The auxiliary electrode can be connected to the cathode in a contact hole CH.

The contact hole CH can be provided in the non-emission area NEA as illustrated in FIG. 4, but can also be provided in the light emission area EA.

For example, in a light emitting display panel 100 in which light is emitted in a direction toward the anode configuring the light emitting device ED, the contact hole CH can be provided in the non-light emission area NEA, and in a light emitting display panel 100 in which light is emitted in a direction toward the cathode configuring the light emitting device ED, the contact hole CH can be provided in the light emission area EA. However, even in a light emitting display panel 100 in which light is emitted in a direction toward the cathode configuring the light emitting device ED, the contact hole CH can be provided in the non-emission area NEA.

Hereinafter, as illustrated in FIG. 4, a light emitting display panel, in which a contact hole CH in which the auxiliary electrode and the cathode are connected is provided in the non-emission area NEA, and particularly, the contact hole CH is provided in the bank distinguishing the pixels P, will be described as an example of the light emitting display panel 100 applied to an embodiment of the present disclosure. In this case, the contact hole CH can be included in each of the pixels P, as illustrated in FIG. 4, but the present disclosure is not limited thereto. Accordingly, the contact hole CH can be provided in at least one of the pixels P provided in the light emitting display panel 100.

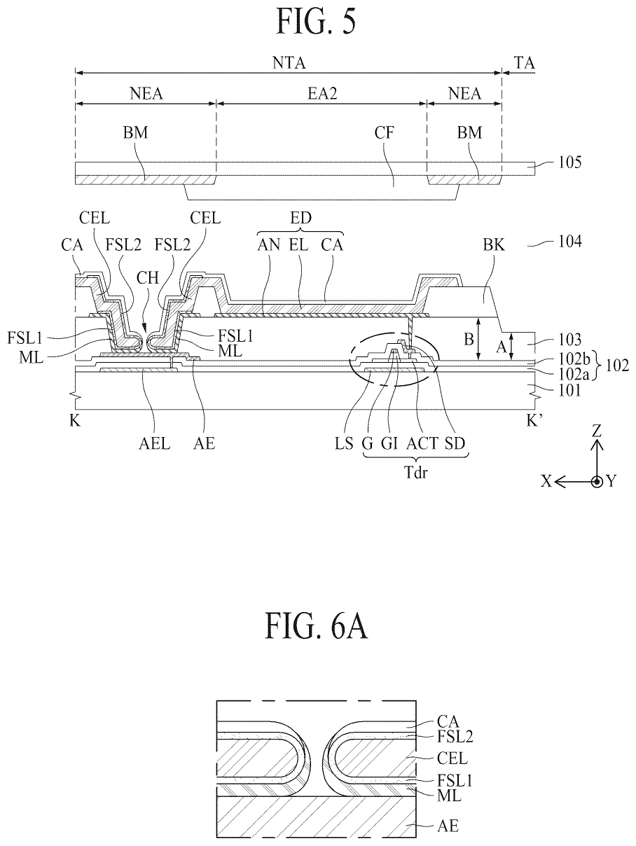

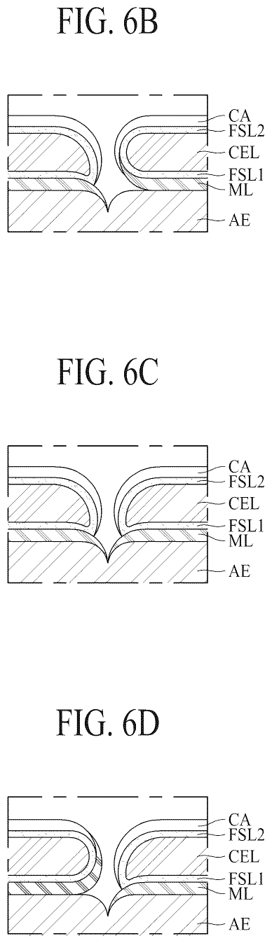

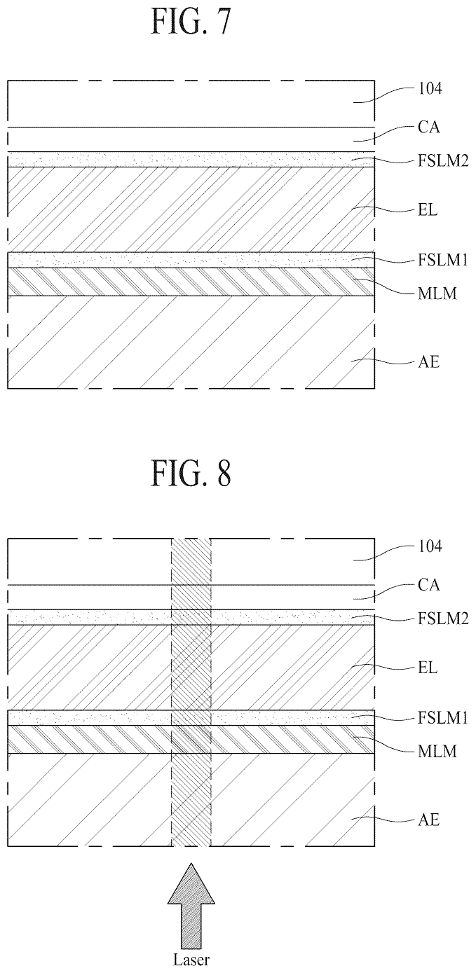

FIG. 5 is an exemplary diagram illustrating a cross-sectional surface taken along line K-K′ illustrated in FIG. 4 according to one embodiment, FIG. 6A to FIG. 6D are exemplary diagrams illustrating a structure in which a metal layer and cathode illustrated in FIG. 5 are connected according to one embodiment, and FIGS. 7 and 8 are exemplary diagrams illustrating a method of connecting the metal layer and cathode illustrated in FIG. 5 according to one embodiment. Particularly, the cross-sectional surface illustrated in FIG. 5 can be applied not only to the second pixel P2 illustrated in FIG. 4 but also to the first pixel P1, third pixel P3, and fourth pixel P4.

The light emitting display apparatus according to an embodiment of the present disclosure can include a substrate 101 including a display area DA and a non-display area NDA, a light emitting layer EL (e.g., a light emission layer) provided in pixels P in the display area DA, a cathode CA provided on the light emitting layer EL, and an auxiliary electrode AE connected to the cathode CA in a contact hole CH provided in each of the pixels P. Particularly, an upper surface, a lower surface, and a side surface of a contact-area light emitting layer CEL provided in the contact hole CH, among the light emitting layer, can be wrapped by a fluorine-based protective layer. The light emitting device ED can include the anode AN, the light emitting layer EL, and the cathode CA. In one embodiment, the contact-area light emitting layer CEL is a portion of the light emitting layer EL that extends into the contact hole CH in the non-emission area NEA.

For example, referring to FIG. 5, a pixel driving circuit layer 102 including transistors which drive pixels P is provided on a substrate 101, a planarization layer 103 planarizing the driving circuit layer 102 is provided on the pixel driving circuit layer 102, anodes AN included in the pixels P are provided on the planarization layer 103, the anodes AN are covered by a light emitting layer EL, an auxiliary electrode AE is provided in the pixel driving circuit layer 102, a contact hole CH in which the auxiliary electrode AE and a cathode CA are connected passes through the planarization layer 103, ends of the anodes AN are covered by a bank BK, the anodes AN and the banks BK are covered by a light emitting layer EL, and the light emitting layer EL is covered by the cathode CA, and the cathode CA is covered by an encapsulation layer 104. Color filters CF are provided in an area corresponding to (e.g., overlapping) the anodes AN at an upper end of the encapsulation layer 104, a black matrix BM is provided between the color filters CF, and the color filters CF and the black matrixes BM can be provided in the encapsulation substrate 105.

The substrate 101 can be a transparent glass substrate or a transparent plastic substrate.

A pixel driving circuit layer 102 can be provided on the substrate 101. The pixel driving circuit layer 102 can include at least two insulation layers and at least two metal layers, and the pixel driving circuit layer 102 can be provided with the transistors Tsw1, Tsw2, and Tdr described with reference to FIG. 2. In FIG. 5, the driving transistor Tdr among the transistors Tsw1, Tsw2, and Tdr illustrated in FIG. 2 is illustrated. The light emitting display panel 100 illustrated in FIG. 5 is provided with a color filter CF at an upper end of the cathode CA. Accordingly, light generated from the light emitting device ED can be emitted to the outside through the cathode CA and the color filter CF.

Accordingly, the light emission area EA can be provided with at least one of the transistors Tsw1, Tsw2, and Tdr included in the pixel driving circuit PDC, for example, as illustrated in FIG. 5, the driving transistor Tdr can be provided in the light emission area EA. Therefore, in the following description, when the driving transistor Tdr does not need to be specifically mentioned, the driving transistor Tdr illustrated in FIG. 5 can be referred to as a transistor.

The pixel driving circuit layer 102 can include a light blocking layer LS, a buffer 102a covering the light blocking layer LS, an active ACT provided on the buffer 102a, a gate insulation layer GI provided on the active ACT, a gate G provided on the gate insulation layer GI, a passivation layer 102b covering the gate G, and a source/drain SD provided on the passivation layer 102b. The pixel driving circuit layer 102 can further include another passivation layer covering the source/drain SD. Another passivation layer can be included in the planarization layer 103.

The light blocking layer LS can be disposed in the non-transmission area NTA. The light blocking layer LS can be disposed to overlap a transistor provided in the pixel driving circuit layer 102, and particularly, can be disposed to overlap the driving transistor Tdr.

For example, the light blocking layer LS can be disposed to overlap the active ACT of the driving transistor Tdr to block external light incident on the active ACT from the outside. The light blocking layer LS can be formed of any one of molybdenum (Mo), aluminum (Al), chromium (Cr), gold (Au), titanium (Ti), nickel (Ni), neodymium (Nd), and copper (Cu), or can be formed of an alloy thereof. The light blocking layer LS can be formed as a single layer or a multilayer.

Signal lines can be provided on the substrate 101 along with a light blocking layer LS. Signal lines can be, for example, data lines DL.

The buffer 102a, the gate insulation layer GI, and the passivation layer 102b can be insulation layers, and the light blocking layer LS, the gate G, and the source/drain SD can be metal layers.

Each of the transistors Tsw1, Tsw2, and Tdr provided in the pixel driving circuit layer 102 can be formed by an active ACT, a gate insulation layer GI, and a gate G.

The buffer 102a can be formed as a single layer, or can be formed as at least two inorganic layers. For example, the buffer 102a can be formed as a single layer by using any one of silicon oxide (SiOx), silicon nitride (SiNx), and silicon oxynitride (SiOxNy). Moreover, the buffer 102a can be formed as a multilayer by using at least two materials among silicon oxide (SiOx), silicon nitride (SiNx), and silicon oxynitride (SiOxNy).

The buffer 102a can be formed on the entire upper surface in order to block ions or impurities diffusing from the substrate 101 and to block moisture penetrating into the thin film transistor TFT or light emitting device through the substrate 101.

An active ACT can be disposed on the buffer 102a. The active ACT can be formed of a silicon-based semiconductor material or an oxide-based semiconductor material. The active ACT can include a channel area overlapping the gate G and source/drain areas provided at both ends of the channel area.

The gate insulation layer GI can be provided on the active ACT. The gate insulation layer GI can perform a function of insulating the active ACT and the gate G. The gate insulation layer GI can be formed of an inorganic insulation material. For example, the gate insulation layer GI can be formed as a single layer by using any one of silicon oxide (SiOx), silicon nitride (SiNx), and silicon oxynitride (SiOxNy). Moreover, the gate insulation layer GI can be formed as a multilayer by using at least two materials among silicon oxide (SiOx), silicon nitride (SiNx), and silicon oxynitride (SiOxNy).

As illustrated in FIG. 5, the gate insulation layer GI can be provided only in the area corresponding to the gate G on an upper end of the active ACT, or can be provided to cover the entire active ACT.

Accordingly, the gate insulation layer GI can be provided only in the non-transmission area NTA. Moreover, even when the gate insulation layer GI is provided in the transmission area TA, the gate insulation layer GI can be disposed only in a portion of the transmission area TA in order to improve the light transmittance of the transmission area TA.

A gate G can be provided on the gate insulation layer GI. The gate G can be provided to overlap the active layer ACT with the gate insulation layer GI interposed therebetween.

The gate G can be formed of any one of molybdenum (Mo), aluminum (Al), chromium (Cr), gold (Au), titanium (Ti), nickel (Ni), neodymium (Nd), and copper (Cu), formed of an alloy thereof, or can be formed as a single layer or multilayers.

A passivation layer 102b can be provided on the gate G and the buffer layer 102a. The passivation layer 102b can be provided to cover the gate G. The passivation layer 102b can perform a function of protecting the transistor. The passivation layer 102b can be formed as a single layer or as a multilayer by using at least one of silicon oxide (SiOx), silicon nitride (SiNx), and silicon oxynitride (SiOxNy).

The passivation layer 102b can be disposed in the non-transmission area NTA. Moreover, even when the passivation layer 102b is provided in the transmission area TA, the passivation layer 102b can be provided only in a portion of the transmission area TA in order to improve the light transmittance of the transmission area TA.

A source/drain SD can be disposed on the passivation layer 102b. The source/drain SD can be connected to a first or second electrode of a transistor through a transistor contact hole formed in the passivation layer 102b.

The first or second electrode of the transistor can be a source/drain area provided at both ends of a channel area of the active ACT.

For example, one source/drain SD provided on the passivation layer 102b can be connected to the first electrode of the transistor, and another source/drain SD provided on the first passivation layer 102b can be connected to the second electrode of the transistor.

The source/drain SD can be formed of any one of molybdenum (Mo), aluminum (Al), chromium (Cr), gold (Au), titanium (Ti), nickel (Ni), neodymium (Nd), and copper (Cu), formed of an alloy thereof, or can be formed as a single layer or multilayers.

A planarization layer 103 can be provided on the pixel driving circuit layer 102. The planarization layer 103 can perform a function of covering and protecting the transistors and can perform a function of planarizing an upper end of the pixel driving circuit layer 102.

The planarization layer 103 can be formed by using at least one of organic and inorganic materials, and can be formed as a single layer or multilayers.

For example, the planarization layer 103 can be formed as a single layer or a multilayer by using at least one of a silicon oxide film (SiOx), a silicon nitride film (SiNx), and a silicon oxynitride film (SiOxNy).

A step height can be formed at the boundary between the non-transmission area NTA and the transmission area TA of the planarization layer 103. In this case, as illustrated in FIGS. 6 and 7, the height A (e.g., a thickness) of the planarization layer 103 provided in the transmission area TA can be less than the height B (e.g., a thickness) of the planarization layer 103 provided in the non-transmission area NTA. As the height of the planarization layer 103 is reduced, light transmittance in the transmission area TA can be improved. Thus, a portion of the planarization layer 103 in the emission area EA and non-emission area NEA is thicker than a portion of the planarization layer 103 in the transmission area TA.

The step height of the planarization layer 103 at the boundary between the transmission area TA and the non-transmission area NTA can be formed by etching the planarization layer 103 provided in the transmission area TA, or can be formed because the buffer 102a and the gate insulation layer GI are not provided at a lower end of the planarization layer 103 in the transmission area TA.

Anodes AN can be provided on the planarization layer 103. The anode AN can be disposed in the non-transmission area NTA.

The anode AN can be connected to the first or second electrode of the driving transistor Tdr through a planarization-layer contact hole passing through the planarization layer 103.

The anode AN can be formed of any one of a metal, a metal alloy, and a combination of metal and oxide. For example, the anode AN can be formed in a multilayer structure including a transparent electrode layer formed of a transparent conductive material and a reflective electrode layer formed of an opaque conductive material with high reflection efficiency.

The transparent electrode layer of the anode AN can be formed of a material with a relatively high work function value, such as indium tin oxide (ITO) or indium zinc oxide (IZO). The reflective electrode layer of the anode AN can be formed of any one of silver (Ag), aluminum (Al), copper (Cu), molybdenum (Mo), titanium (Ti), nickel (Ni), chromium (Cr), and tungsten, or can be formed of an alloy thereof.

More specifically, the anode AN can be formed in a structure in which a transparent electrode layer, a reflective electrode layer, and a transparent electrode layer are sequentially stacked, or in a structure in which a transparent electrode layer and a reflective electrode layer are sequentially stacked, and can be formed in various combinations.

Banks BK can be provided on the ends of the anodes AN. Particularly, the bank BK can be provided in the non-transmission area NTA.

For example, the bank BK can be formed of an inorganic material such as silicon oxide (SiOx), silicon nitride (SiNx), and silicon oxynitride (SiOxNy). Moreover, the bank BK can be formed of an organic material such as polyimide, acrylate, and benzocyclobutene series resin.

The bank BK covers the ends (e.g., edges) of the anode AN. Light can be output from an area (hereinafter simply referred to as an opening portion) of the anode AN which is not covered by the bank BK. Accordingly, the opening portion of the anode AN exposed by the bank BK can become the light emission area EA, and the portion where the bank BK is formed can become the non-emission area NEA.

Furthermore, each of the pixels P1, P2, P3 and P4 can be distinguished by the banks BK, and the transmission area TA and the non-transmission area TA can be distinguished by the banks BK.

In this case, the bank BK adjacent to the transmission area TA can include an inclined surface corresponding to the inclined surface of the planarization layer 103, as illustrated in FIG. 5.

For example, the inclined surface of the bank BK can have the same or similar inclined angle as the inclined surface of the planarization layer 103 so that the inclined surface of the bank BK is aligned with the inclined surface of the planarization layer 103. In this case, the inclined surface of the bank BK and the inclined surface of the planarization layer 103 can be continuous. Alternatively, the inclined surface of the bank BK can have a lower inclined angle than the inclined surface of the planarization layer 103. In this case, the inclined surface of the bank BK and the inclined surface of the planarization layer 103 can be continuous. Alternatively, the inclined surface of the bank BK can be offset from the inclined surface of the planarization layer 103, and in this case, a step-shaped structure can be formed between the bank BK and the planarization layer 103.

A light emitting layer EL can be provided on the anode AN and the bank BK.

Accordingly, the light emitting layer EL can be provided in the non-transmission area NTA. However, the light emitting layer EL can also be provided in the transmission area TA. In FIG. 5, a light emitting display panel 100 provided with a light emitting layer EL only in the non-transmission area NTA is illustrated.

A cathode CA is provided on the light emitting layer EL.

The cathode CA can be provided only in the non-transmission area NTA, but can be provided in the entire transmission area TA or only a part of the transmission area TA. FIG. 5 illustrates a light emitting display panel 100 provided with a cathode CA only in the non-transmission area NTA.

An encapsulation layer 104 can be provided on the entire surface of the substrate 101. The encapsulation layer 104 can be provided in both the transmission area TA and the non-transmission area NTA.

For example, the encapsulation layer 104 can include lithium fluoride (LiF), and can also include inorganic materials such as silicon oxide (SiOx), silicon nitride (SiNx), and silicon oxynitride (SiOxNy). Moreover, the encapsulation layer 104 can be formed as multilayers including organic and inorganic materials.

The encapsulation layer 104 can be an adhesive material for bonding the substrate 101 and the encapsulation substrate 105 provided with the color filter CF and the black matrix BM.

Color filters CF can be provided in an area corresponding to (e.g., overlapping) the anodes AN at an upper end of the encapsulation layer 104.

For example, the first pixel P1 can be provided with a blue color filter CF, the second pixel P2 can be provided with a red color filter CF, and the third pixel P3 can be provided with a green color filter CF. Accordingly, blue light can be output from the first pixel P1, red light can be output from the second pixel P2, and green light can be output from the third pixel P3.

However, because white light is output from the fourth pixel P4, a color filter may not be provided in the area corresponding to the fourth pixel P4 at an upper end of the encapsulation layer 104.

A black matrix BM can be provided between the color filters CF. Color filters CF can be distinguished by the black matrix BM. The black matrix BM can be provided to face the banks BK surrounding the pixel P.

An encapsulation substrate 105 can be provided on the black matrix BM and the color filter CF.

For example, the encapsulation substrate 105 can be bonded to the upper end of the black matrix BM and the color filter CF.

However, the color filters CF and the black matrix BM can be provided on the encapsulation substrate 105, and the encapsulation substrate 105 provided with the color filters CF and the black matrix BM can be bonded to the substrate 101 provided with the pixels P through the encapsulation layer 104.

Alternatively, the encapsulation substrate 105 provided with color filters CF and the black matrix BM can be bonded to the substrate 101 provided with the pixels P through an adhesive material applied on the encapsulation layer 104.

In this case, the encapsulation substrate 105 can be a transparent glass substrate or a transparent plastic substrate.

Accordingly, the encapsulation layer 104 can be provided between the anodes AN provided in the first pixel P1, the second pixel P2, and the third pixel P3 and the color filters CF, and the encapsulation layer 104 can be provided between the anode AN provided in the fourth pixel P4 and the encapsulation substrate 105.

Finally, the auxiliary electrode AE can be provided on the pixel driving circuit layer 102, or can be provided on any one of insulating layers configuring the pixel driving circuit layer 102.

For example, as illustrated in FIG. 5, the auxiliary electrode AE can be provided on the passivation layer 102b configuring the pixel driving circuit layer 102 and covered by the planarization layer 103.

Alternatively, the auxiliary electrode AE can be provided on the buffer 102a configuring the pixel driving circuit layer 102 and covered by the passivation layer 102b.

The auxiliary electrode AE can be connected to the auxiliary electrode line AEL that is connected to the power supply 500. An auxiliary voltage can be supplied to the auxiliary electrode AE through the power supply 500 and the auxiliary electrode line AEL.

The auxiliary voltage can be the same as or similar to the second voltage EVSS supplied to the cathode CA.

At least one insulation layer is between the auxiliary electrode line AEL and the auxiliary electrode AE.

For example, the auxiliary electrode line AEL can be provided on the buffer 102a, and the auxiliary electrode AE can be provided on the passivation layer 102b covering the buffer 102a.

Alternatively, the auxiliary electrode line AEL can be provided on the substrate 101 as illustrated in FIG. 5, and the auxiliary electrode AE can be provided on the pixel driving circuit layer 102. In this case, a light blocking layer LS can be provided on the substrate 101 along with the auxiliary electrode line AEL.

The auxiliary electrode line AEL can be provided along the first direction or the second direction. For example, the auxiliary electrode line AEL can be provided in parallel with the gate line GL or the data line DL.

For example, the auxiliary electrode AE can be connected to the auxiliary electrode line AEL through a circuit-layer contact hole provided in the pixel driving circuit layer 102.

Hereinafter, as illustrated in FIG. 5, a light emitting display panel, in which the auxiliary electrode line AEL is provided on the substrate 101 together with the light blocking layer LS and the auxiliary electrode AE is provided on the pixel driving circuit layer 102 to be covered by the planarization layer 103, will be described as an example of a light emitting display panel 100.

In this case, the cathode CA can be connected to the auxiliary electrode AE through a contact hole CH provided in each of the pixels P.

Particularly, in the contact hole CH, the cathode CA can be connected to (e.g., in direct contact) the metal layer ML (e.g., a conductive layer) connected to the auxiliary electrode AE. For example, the cathode CA can be electrically connected to the auxiliary electrode AE through the metal layer ML that is in direct contact with the auxiliary electrode AE in the contact hole CH.

The metal layer ML can include the same material as the anode AN provided at a lower surface of the light emitting layer EL in each of the pixels P. For example, the metal layer ML cam be provided in each of the pixels P through the same process as the process in which the anode AN is provided.

The contact hole CH can pass through the bank BK and the planarization layer 103, and the auxiliary electrode AE can be exposed at a lower end of the contact hole CH.

An upper surface, a lower surface that is opposite the upper surface, and a side surface that is between the upper surface and the lower surface of a contact-area light emitting layer CEL provided in the contact hole, among the light emitting layer, can be wrapped by a fluorine-based protective layer FSL1 and FSL2. As further described below, the fluorine-based protective layer FSL1 and FSL2 prevent moisture from penetrating the contact-area light emitting layer and propagating to the emission layer EL. In one embodiment, the fluorine-based protective layer FSL1 and FSL2 is a moisture blocking layer that wraps around a portion of the light emitting layer EL that is in the contact hole CH (e.g., the contact-area light emitting layer CEL). In FIG. 5, the contact-area light emitting layer CEL in the contact hole CH is divided into two areas. This is because FIG. 5 illustrates a cross-sectional surface of the contact hole CH. For example, the two contact-area light emitting layers CEL, which are divided into two areas in FIG. 5, are substantially formed continuously along the lower and side surfaces of the contact hole CH. Therefore, in the following description, the connection relationship between the cathode CA and the auxiliary electrode AE will be described using a contact-area light emitting layer CEL connected to the light emitting layer EL among the two contact-area light emitting layers CEL illustrated in FIG. 5, as an example. That is, taking the contact-area light emitting layer CEL illustrated on the right among the two contact-area light emitting layers CEL provided in the contact hole CH in FIG. 5 as an example, the connection relationship between the cathode CA and the auxiliary electrode AE will be described.

As described above, a plurality of surface of the contact-area light emitting layer CEL such as the upper, lower, and side surfaces of the contact-area light emitting layer CEL provided in the contact hole CH in the light emitting layer EL can be wrapped by the fluorine-based protective layers FSL1 and FSL2.

For example, a first fluorine-based protective layer FSL1 can be provided on (e.g., cover) the lower surface of the contact-area light emitting layer CEL that is overlapped by the upper surface of the contact-area light emitting layer CEL, a second fluorine-based protective layer FSL2 can be provided on (e.g., cover) the upper surface of the contact-area light emitting layer CEL that is overlapped by the lower surface of the contact-area light emitting layer CEL and the first fluorine-based protective layer FLS1, and the side surface of the contact-area light emitting layer CEL that is connected to the upper and lower surface of the contact-area light emitting layer CEL can be wrapped (e.g., covered) by one of the first fluorine-based protective layer FSL1 and the second fluorine-based protective layer FSL2. In other words, the fluorine-based protective layer includes a first portion (e.g., the first fluorine-based protective layer FSL1) that is in direct contact with a first surface of the portion of the light emitting layer EL in the contact hole CH (e.g., a lower surface of the contact-area light emitting layer CEL), a second portion (e.g., the second fluorine-based protective layer FSL2) that is direct contact with a second surface of the portion of the light emission layer that is spaced apart from the first surface (e.g., an upper surface of the contact-area light emitting layer CEL), and a third portion that is in direct contact with a third surface of the portion of the light emission layer (e.g., a side surface of the contact-area light emitting layer CEL) that is between the first surface and the second surface of the portion of the light emission layer that is in the contact hole. The third portion may be a portion of the second fluorine-based protective layer FSL2 or the first fluorine-based protective layer FSL1.

In this case, the cathode CA can be connected to the metal layer ML at the side surface of the contact-area light emitting layer CEL. The metal layer ML is connected to the auxiliary electrode AE, and the auxiliary electrode AE is connected to the auxiliary electrode line AEL. Accordingly, the cathode CA can be connected to the auxiliary electrode line AEL through the metal layer ML and the auxiliary electrode AE. Therefore, the auxiliary voltage supplied through the auxiliary electrode line AEL can be supplied to the cathode CA.

The first fluorine-based protective layer FSL1 can be provided between the metal layer ML and the lower surface of the contact-area light emitting layer CEL, and the second fluorine-based protective layer FSL2 can be provided between the cathode CA and the upper surface of the contact-area light emitting layer CFL. That is, a first portion of the fluorine-based protective layer (e.g., the first fluorine-based protective layer FSL1) is between the contact-area light emitting layer CEL and the metal layer ML in the contact hole CH, and a second portion of the fluorine-based protective layer (e.g., the second fluorine-based protective layer FSL2) is between the contact-area light emitting layer CEL and the portion of the cathode electrode CA in the contact hole CH.

In this case, the side surface of the contact-area light emitting layer CEL means each of the surfaces facing each other in the two contact-area light emitting layers CEL illustrated in FIG. 5. For example, among the surfaces of the two contact-area light emitting layers CEL provided in the contact hole CH, the surfaces arranged to face each other at a lower end of the contact hole CH can be the side surfaces of the contact-area light emitting layers CEL.

The side surfaces of the contact-area light emitting layers CEL can be spaced apart from each other as illustrated in FIG. 5, or can be in contact with each other. When the side surfaces of the two contact-area light emitting layers CEL are spaced apart from each other as illustrated in FIG. 5, the auxiliary electrode AE can be exposed through the spaced gap.

For example, the auxiliary electrode AE is provided in the contact hole CH, and the metal layer ML provided on the auxiliary electrode AE can be connected to the cathode CA on the side surface of the contact-area light emitting layer CEL.

As described above, the metal layer ML can include the same material as the anode AN provided at the lower end of the light emitting layer EL in each of the pixels P.

In this case, a portion of the cathode CA provided on the side surface of the contact-area light emitting layer CEL can be covered by a portion of the metal layer ML as illustrated in the left side of each of FIGS. 6A and 6B. Alternatively, an end (e.g., a portion) of the metal layer ML provided on the side surface of the contact-area light emitting layer CEL can be covered by a portion of the cathode CA as illustrated in the right side of FIG. 6B. Alternatively, an end (e.g., a portion of) of the metal layer ML provided on the side surface of the contact-area light emitting layer CEL can be connected to the metal layer ML as illustrated in the left side of FIG. 6B, the right side of FIG. 6C and the right side of FIG. 6D.

To provide an additional description, the metal layer ML and the cathode CA can be connected to each other in various structures as illustrated in FIG. 6A to FIG. 6D, and thus, the cathode CA can be electrically connected to the auxiliary electrode AE through the metal layer ML. The metal layer ML and the cathode CA can be connected to each other in various structures other than those illustrated in FIG. 6A to FIG. 6D.

To provide an additional description, as illustrated in FIG. 5, a pixel driving circuit layer 102 including transistors which drive pixels P can be provided in the substrate 101, a planarization layer 103 planarizing the pixel driving circuit layer 102 can be provided on the pixel driving circuit layer 102, anodes AN included in the pixels P can be provided on the planarization layer 103, the anodes AN can be covered by the light emitting layer EL, the auxiliary electrode AE can be provided in the pixel driving circuit layer 102, and the contact hole CH where the auxiliary electrode AE and the cathode CA are connected can pass through the planarization layer 103.

In this case, the auxiliary electrode AE can be exposed at the lower end of the contact hole CH. However, when the side surfaces of the two contact-area light emitting layers CEL are in contact with or adjacent to each other, the auxiliary electrode AE may not be exposed at the lower end of the contact hole CH.

When the contact hole CH is provided in an area where the bank BK is provided, the contact hole CH can pass through the bank BK and the planarization layer 103.

When the auxiliary electrode AE is provided at a lower end of any one of the insulation layers configuring the pixel driving circuit layer 102, the contact hole CH can extend to any one of the insulating layers configuring the pixel driving circuit layer 102. In this case, a portion of the auxiliary electrode AEL can be exposed in the contact hole CH. That is, a portion of the auxiliary electrode AE in the contact hole CH is non-overlapped by the metal layer ML, the contact-area light emitting layer CEL in the contact hole, the fluorine-based protective layer FSL1, FSL2, and the portion of the cathode electrode CA in the contact hole CH.

The metal layer ML can be provided on a sidewall of the contact hole CH, the first fluorine-based protective layer FSL1 can be provided on the metal layer ML, the contact-area light emitting layer CEL can be provided on the first fluorine-based protective layer FSL1, the second fluorine-based protective layer FSL2 can be provided on the contact-area light emitting layer CEL, the cathode CA can be provided on the second fluorine-based protective layer FSL2, and the metal layer ML can be connected to the auxiliary electrode AE at the lower end of the contact hole CH.

For example, the metal layer ML can be provided only at the lower end of the contact hole CH, but as illustrated in FIG. 5, can also be provided on the sidewall of the contact hole CH. Particularly, the metal layer ML can extend from the sidewall of the contact hole CH, for example, a side surface of the planarization layer 103 to the upper surface of the planarization layer 103. The metal layer ML provided on the upper surface of the planarization layer 103 can be covered by the bank BK.

The first fluorine-based protective layer FSL1 can be provided to cover the metal layer ML.

The contact-area light emitting layer CEL can cover the first fluorine-based protective layer FSL1, and particularly, can extend in the direction toward the anode AN through the side and upper surfaces of the bank BK.

The second fluorine-based protective layer FSL2 can cover the contact-area light emitting layer CEL provided in the contact hole CH.

As described above, the side surface of the contact-area light emitting layer CEL provided at the lower end of the contact hole CH can be wrapped by at least one of the first fluorine-based protective layer FSL1 and the second fluorine-based protective layer FSL2.

The cathode CA can be connected to the metal layer ML on the side surface of the contact-area light emitting layer CEL.

In this case, the cathode CA provided on the side surface of the contact-area light-emitting layer CEL can cover at least one of the first fluorine-based protective layer FSL1 and the second fluorine-based protective layer FSL2 which are provided on the side surface of the contact-area light-emitting layer CEL. The metal layer ML provided on the side surface of the contact-area light-emitting layer CEL can cover at least one of the first fluorine-based protective layer FSL1 and the second fluorine-based protective layer FSL2 which are provided on the side surface of the contact-area light-emitting layer CEL.

For example, because the first fluorine-based protective layer FSL1 and the second fluorine-based protective layer FSL2 extend to the side surface of the contact-area light emitting layer CEL, the first fluorine-based protective layer FSL1 and the second fluorine-based protective layer FSL2 can be covered by at least one of the cathode CA and the metal layer ML.

The connection structure between the cathode CA and the metal layer ML, described above with reference to FIGS. 5 and 6A to 6B, can be obtained by a welding process using a laser.

For example, in the manufacturing process of the light emitting display panel 100, as shown in FIG. 7, the auxiliary electrode AE, a metal layer material MLM, a first fluorine-based material FSLM1, a second fluorine-based material FSLM2, and the cathode CA are sequentially stacked in the contact hole CH.

The encapsulation layer 104 can be provided on the cathode CA, and the color filter CF, the black matrix BM, and the encapsulation substrate 105 can be provided on the encapsulation layer 104.

Alternatively, the substrate 101 provided with the cathode CA can be bonded to the encapsulation substrate 105 provided with the color filter CF and the black matrix BM through the encapsulation layer 104.

Thereafter, as illustrated in FIG. 8, when the laser is injected into the center portion of the contact hole CH, an area where the laser is injected in the metal layer material MLM, the first fluorine-based material FSLM1, the second fluorine-based material FSLM2, and the cathode CA can be deformed, so that the cathode CA and the metal layer material MLM can be bonded in various shapes as illustrated in FIG. 6. For example, by the tunneling effect, the cathode CA and the metal layer material MLM can be bonded in various shapes as illustrated in FIG. 6.

Accordingly, the metal layer ML and the cathode CA can be bonded, and the contact-area light emitting layer CEL wrapped by the first fluorine-based protective layer FSL1 and the second fluorine-based protective layer FSL2 can be provided inside the metal layer ML and the cathode CA.

For example, an end of the metal layer material MLM where a laser is injected can be rolled to be moved toward the cathode CA, and an end of the cathode CA where a laser is injected can be rolled to be moved toward the metal layer material MLM. The metal layer material MLM cut by the laser can become the metal layer ML. Accordingly, the end of the metal layer ML and the end of the cathode CA can be connected in the shape as illustrated in FIG. 6a, and in addition to the shape, can be connected in various shape as illustrated in FIGS. 6b to 6d.

The first fluorine-based material FSLM1 can be cut by the laser to form the first fluorine-based protective layer FSL1, and the second fluorine-based material FSLM2 can be cut by the laser to form the second fluorine-based protective layer FSL1.

The first fluorine-based protective layer FSL1 provided on the metal layer ML can be moved toward the cathode CA together with the metal layer ML when the end of the metal layer ML is rolled to be moved toward the cathode CA. Accordingly, the end of the first fluorine-based protective layer FSL1 can be rolled to wrap the side surface of the contact-area light emitting layer CEL.

Moreover, the second fluorine-based protective layer FSL2 provided at the lower end of the cathode can be moved toward to the metal layer ML together with the cathode CA when the end of the cathode CA is rolled to be moved toward the metal layer ML. Accordingly, the end of the second fluorine-based protective layer FSL2 can be rolled to wrap the side surface of the contact-area light emitting layer CFL.

Therefore, the lower surface of the contact-area light emitting layer CEL can be wrapped by the first fluorine-based protective layer FSL1, the upper surface of the contact-area light emitting layer CEL can be wrapped by the second fluorine-based protective layer FSL2, and the side surface of the contact-area light emitting layer CEL can be wrapped by at least one of the first fluorine-based protective layer FSL1 and the second fluorine-based protective layer FSL2.

In this case, the metal layer ML provided at the lower end of the contact-area light emitting layer CEL and the cathode CA provided on the contact-area light emitting layer CEL can be connected to each other in various structures as illustrated in FIGS. 6A to 6B in the side surface of the contact-area light emitting layer CEL.

According to the structure described above, the side surface of the contact-area light emitting layer CEL can be covered by the first fluorine-based protective layer FSL1 and the second fluorine-based protective layer FSL2. Therefore, moisture penetrating in the direction toward the contact hole CH through the encapsulation layer 104 can be blocked by the first fluorine-based protective layer FSL1 and the second fluorine-based protective layer FSL2, and thus, cannot penetrate into the inside of the contact-area light emitting layer CEL through the side surface of the contact-area light emitting layer CEL.

For example, when the cathode CA and the metal layer ML are connected by a laser process, moisture can penetrate in the direction toward the side surface of the contact-area light emitting layer CEL through the encapsulation layer 104. However, as described above, because the side surface of the contact-area light emitting layer CEL is covered by the first fluorine-based protective layer FSL1 and the second fluorine-based protective layer FSL2, moisture in the encapsulation layer 104 cannot penetrate into the inside of the contact-area light emitting layer ECL through the side surface of the contact-area light emitting layer CEL.

In this case, because the lower surface of the contact-area light emitting layer CEL is covered by the first fluorine-based protective layer FSL1 and the upper surface of the contact-area light emitting layer CEL is covered by the second fluorine-based protective layer FSL2 and the cathode CA, moisture cannot penetrate through the upper and lower surfaces of the contact-area light emitting layer CEL.

Moreover, when the cathode CA and the metal layer ML are connected through the side surface of the contact-area light emitting layer CEL, the cathode CA and the metal layer ML may not completely overlap. However, even in an area where the cathode CA and the metal layer ML do not completely overlap, at least one of the first fluorine-based protective layer FSL1 and the second fluorine-based protective layer FSL2 can be provided on the side surface of the contact-area light emitting layer CEL. Accordingly, moisture can be blocked by at least one of the first fluorine-based protective layer FSL1 and the second fluorine-based protective layer FSL2. Therefore, moisture cannot penetrate into the inside of the contact-area light emitting layer CEL through the area where the cathode CA and the metal layer ML do not completely overlap.

Each of the fluorine-based protective layer FSL1 and the second fluorine-based protective layer FLS2 can include a fluorine-based material used in the manufacturing process of a light emitting display panel 100. For example, the fluorine-based material can be a material which functions as an etch stopper for an organic layer in the process of patterning the organic layer of the light emitting display panel 100, or can be a material which functions as a pattern mask in the process of patterning the organic layer of the light emitting display panel 100.

In more detail, the fluorine-based material can be a fluoropolymer. In a fluoropolymer, carbon-carbon bonds are formed continuously in a chain structure, and the functional group of the fluoropolymer includes a large amount of fluorine (F).

Fluorine-based materials contain a large amount of fluorine (F) and thus, can have orthogonality. An orthogonality can mean a characteristic in which two objects exist independently, regardless of each other. Accordingly, fluorine-based materials can have both hydrophobic properties, which have low affinity for water, and oleophobic properties, which have low affinity for oil. Due to this orthogonality, the fluorine-based material can be separated from moisture or reject moisture. The application of fluorine-based materials can be confirmed through TOF-SIMS (Time of flight secondary ion mass spectrometer) analysis.

As described above, because the first fluorine-based protective layer FSL1 and the second fluorine-based protective layer FSL2 cover the lower, upper, and side surfaces of the contact-area light emitting layer CEL, external moisture cannot penetrate into the inside of the contact-area light emitting layer CEL in the contact hole CH.

Particularly, when the cathode CA and the metal layer ML are connected by a laser process, because the side surface of the contact-area light emitting layer CEL is covered by the first fluorine-based protective layer FSL1 and the second fluorine-based protective layer FSL2, external moisture cannot penetrate into the inside of the contact-area light emitting layer CEL through the side surface of the contact-area light emitting layer CEL.

Therefore, when the cathode CA and the metal layer ML are connected by the laser process, moisture cannot penetrate into the inside of the contact-area light emitting layer CEL, and thus, moisture cannot penetrate into the inside of the light emitting layer EL connected to the contact-area light emitting layer CEL. Accordingly, the quality of the light emitting device ED can be maintained for a long time, and thus the quality and reliability of the light emitting display device can be improved.

To provide an additional description, the area deformed by the laser, for example, the side surface of the contact-area light emitting layer CEL, can be vulnerable to moisture penetration, but according to the present disclosure, external defect factors (e.g., moisture) can be blocked by the fluorine-based material. Accordingly, moisture cannot penetrate into the inside of the contact-area light emitting layer CEL through the side surface of the contact-area light emitting layer CEL.

In this case, even if each of the first fluorine-based protective layer FSL1 and the second fluorine-based protective layer FSL2 is formed to a thickness of several nm, the cathode CA and the metal layer ML can be connected by the tunneling effect. Therefore, the light emitting display panel 100 can be driven normally.

Also, during the laser process, cracks may occur in the encapsulation layer 104, and thus the threshold voltage of the driving transistor Tdr may shift in the negative (−) direction to cause in defects. However, the shift of the threshold voltage can be prevented or compensated by the first fluorine-based protective layer FSL1 provided in the lower end of the cathode CA, and thus defects due to the shift of the threshold voltage can be prevented.

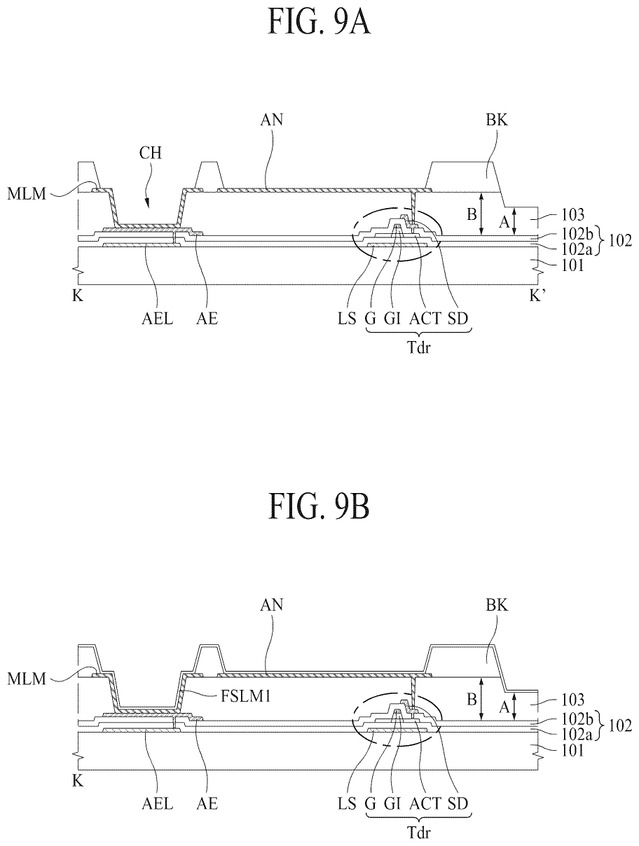

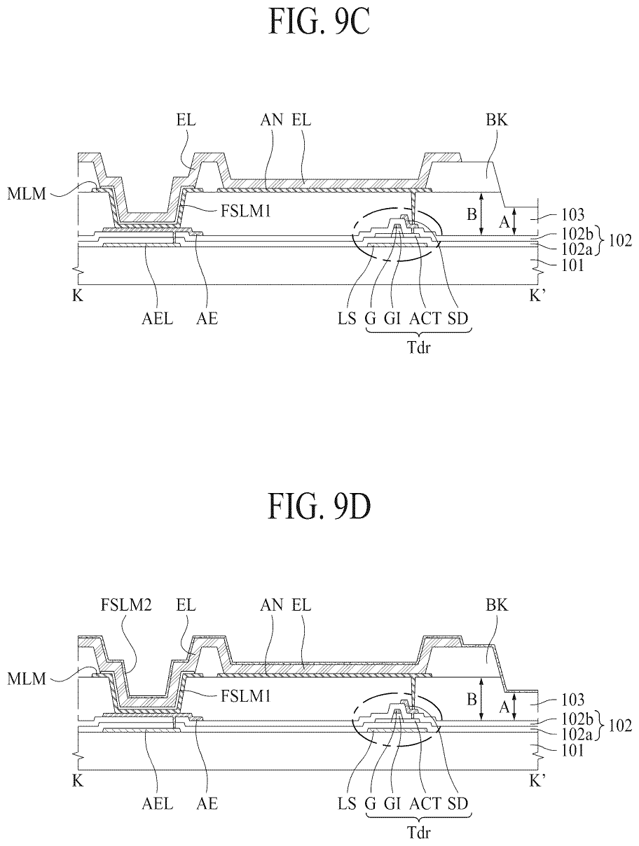

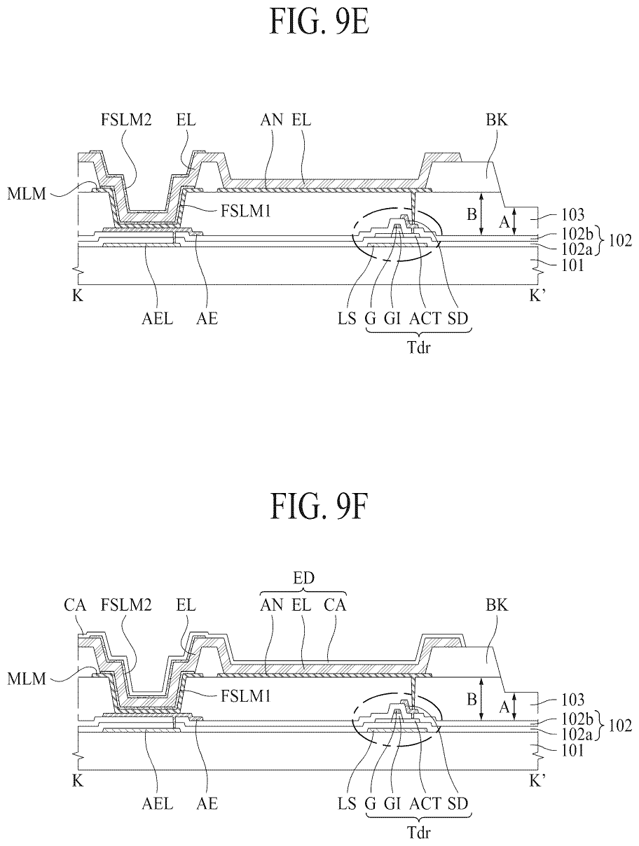

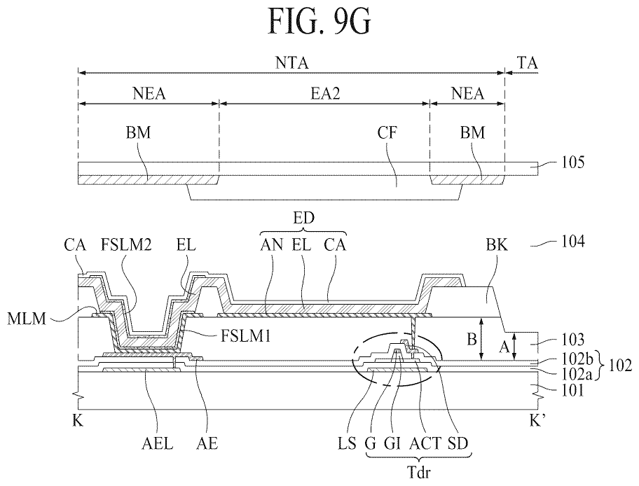

FIGS. 9A to 9G are exemplary diagrams illustrating a method of manufacturing a light emitting display panel according to the present disclosure. In the following description, details which are the same as or similar to details described above with reference to FIGS. 1 to 8 are omitted or will be briefly described.

First, referring to FIG. 9A, a pixel driving circuit layer 102 including a light blocking layer LS, a buffer 102a, an active ACT, a gate insulation layer GI, a gate G, and a source/drain SD can be provided on a substrate 101.

An auxiliary electrode line AEL and an auxiliary electrode AE can be provided on the pixel driving circuit layer 102.

A planarization layer 103 can be provided on the pixel driving circuit layer 102.

Anodes AN can be provided on the planarization layer 103.

Banks BK can be provided outside the anodes AN.

The substrate 101 can include a non-transmission area NTA provided with pixels P and a transmission area TA.

Non-transmission or opaque elements such as transistors Tsw1, Tsw2, and Tdr and a light blocking layer LS can be provided in the pixel driving circuit layer 102 provided in the non-transmission area NTA.

A buffer 102a, a gate insulation layer GI, and a passivation layer 102b can be provided in the pixel driving circuit layer 102 provided in the transmission area TA, and a non-transmission element or an opaque element may not be disposed in the transmission area TA. Moreover, in order to improve the light transmittance of the transmission area TA, at least one of the buffer 102a, the gate insulation layer GI, and the passivation layer 102b configuring the pixel driving circuit layer 102 may not be provided in the transmission area TA.

A step height can be formed between the transmission area TA and non-transmission area NTA of the planarization layer 103 provided on the substrate 101, and an inclined surface can be formed due to the step height.

The anode AN can be provided at a position corresponding to each of the pixels P.

The anode AN can be formed of a metal, a metal alloy, or a combination of metal and oxide. For example, the anode AN can be formed in a multilayer structure including a transparent electrode layer formed of a transparent conductive material and a reflective electrode layer formed of an opaque conductive material with high reflection efficiency.

The transparent electrode layer of the anode AN can be formed of a material with a relatively high work function value, such as indium tin oxide (ITO) or indium zinc oxide (IZO). The reflective electrode layer of the anode AN can be formed of any one of silver (Ag), aluminum (Al), copper (Cu), molybdenum (Mo), titanium (Ti), nickel (Ni), chromium (Cr), and tungsten (W), or can be formed of an alloy thereof.

More specifically, the anode AN can be formed in a structure in which a transparent electrode layer, a reflective electrode layer, and a transparent electrode layer are sequentially stacked, or in a structure in which a transparent electrode layer and a reflective electrode layer are sequentially stacked, and can be formed in various combinations.

A contact hole CH can be formed in the planarization layer 103. The auxiliary electrode AE can be exposed through the contact hole CH.

Through the process of forming the anode AN, a metal layer material MLM can be provided in the contact hole CH, and the metal layer material MLM can be connected to the auxiliary electrode AE exposed through the contact hole CH.

Banks BK can be provided outside the anodes AN. Particularly, the bank BK can be provided in the non-transmission area NTA.

For example, the bank BK can be formed of an inorganic material such as silicon oxide (SiOx), silicon nitride (SiNx), and silicon oxynitride (SiOxNy). Moreover, the bank BK can be formed of an organic material such as polyimide, acrylate, and benzocyclobutene series resin.

The banks BK cover the edges of the anode AN. Light can be output from an area (e.g., an opening portion) of the anode AN which is not covered by the bank BK. Accordingly, the opening portion of the anode AN exposed by the bank BK can become the light emission area EA, and the portion where the bank BK is formed can become the non-emission area NEA.

Furthermore, each of the pixels P can be distinguished by the banks BK, and the transmission area TA and the non-transmission area TA can be distinguished by the banks BK.

In this case, the bank BK adjacent to the transmission area TA can include an inclined surface corresponding to the inclined surface of the planarization layer 103, as illustrated in FIG. 9A.

For example, the inclined surface of the bank BK can have the same or similar inclined angle as the inclined surface of the planarization layer 103. In this case, the inclined surface of the bank BK and the inclined surface of the planarization layer 103 can be continuous. Alternatively, the inclined surface of the bank BK can have a lower inclined angle than the inclined surface of the planarization layer 103. In this case, the inclined surface of the bank BK and the inclined surface of the planarization layer 103 can be continuous. Alternatively, the inclined surface of the bank BK can be offset from the inclined surface of the planarization layer 103, and in this case, a step-shaped structure can be formed between the bank BK and the planarization layer 103.

The bank BK can also be provided with a hole connected to the contact hole CH. For example, the contact hole CH can be exposed through a process of etching the bank BK. In this case, the metal layer material MLM provided on the planarization layer 103 can be covered by the bank BK.

As illustrated in FIG. 9B, the planarization layer 103, the banks BK, and the anodes AN are covered with a first fluorine-based material FSLM1.

The first fluorine-based material FSLM1 can be, for example, a fluoropolymer material. In the fluoropolymer, carbon-carbon bonds are formed continuously in a chain structure, and the functional group of the fluoropolymer includes a large amount of fluorine (F).

The first fluorine-based material FSLM1 contains a large amount of fluorine (F) and thus, can have orthogonality. An orthogonality can mean a characteristic in which two objects exist independently, regardless of each other. Accordingly, the first fluorine-based material FSLM1 can have both hydrophobic properties, which have low affinity for water, and oleophobic properties, which have low affinity for oil. Due to this orthogonality, the first fluorine-based material FSLM1 can be separated from moisture or reject moisture.

The first fluorine-based material FSLM1 can be provided on the substrate 101 by using spin coating or slit coating techniques.

As illustrated in FIG. 9C, the first fluorine-based material FSLM1 can be patterned by a photo process and an exposure process, and the first fluorine-based material FSLM1 can be removed in areas other than the contact hole CH.

The first fluorine-based material FSLM1, the bank BK, the planarization layer 103, and the anode AN can be covered by a light emitting layer EL.

As illustrated in FIG. 9D, a second fluorine-based material FSLM2 can be provided on the light emitting layer EL. The second fluorine-based material FSLM2 can be the same material as the first fluorine-based material FSLM1.

As illustrated in FIG. 9E, the second fluorine-based material FSLM2 can be patterned by a photo process and an exposure process, and the second fluorine-based material FSLM2 can be removed in areas other than the contact hole CH.

In this case, the first fluorine-based material FSLM1 can be provided at a lower end of the light emitting layer EL provided in the contact hole CH, and the second fluorine-based material FSLM12 can be provided on the light emitting layer EL provided in the contact hole CH.

As illustrated in FIG. 9F, a cathode CA can be provided on the second fluorine-based material FSLM2 and the light emitting layer EL.

As illustrated in FIG. 9G, an encapsulation layer 104 can be provided on the cathode CA.

When a color filter CF, a black matrix BM, and an encapsulation substrate 105 are sequentially provided on the encapsulation layer 104, or an encapsulation substrate 105 provided with a color filter CF and a black matrix BM is bonded to the encapsulation layer 104, manufacturing of the light emitting display panel 100 can be completed.

Finally, as described with reference to FIGS. 7 and 8, a laser is injected into the contact hole CH. Therefore, as illustrated in FIGS. 5 and 6, the metal layer ML can be connected to the cathode CA on the side surface of the contact-area light emitting layer CEL, and the side surface of the contact-area light emitting layer CEL can be covered by the first fluorine-based protective layer FSL1 and the second fluorine-based protective layer FSL2.

When the laser process is performed, the lower, upper, and side surfaces of the contact-area light emitting layer CEL can be covered by at least one of the first fluorine-based protective layer FSL1 and the second fluorine-based protective layer FSL2. Accordingly, external moisture cannot penetrate into the inside of the contact-area light emitting layer CEL.

The contact-area light emitting layer CEL is connected to the light emitting layer EL provided on the anode AN. Therefore, if moisture penetration into the contact-area light emitting layer CEL is prevented by the first fluorine-based protective layer FSL1 and the second fluorine-based protective layer FSL2, moisture penetration from the outside into the light emitting layer EL can also be prevented.

Accordingly, the quality of the light emitting device can be improved, and thus the quality of the light emitting display apparatus can be improved.

The features of the light emitting display apparatus according to an embodiment of the present disclosure are briefly summarized as follows.

A light emitting display apparatus according to an embodiment of the present disclosure comprises a substrate including a display area and a non-display area, a light emitting layer provided in pixels provided in the display area, a cathode provided on the light emitting layer, and an auxiliary electrode connected to the cathode through a contact hole provided in each of the pixels, wherein an upper surface, a lower surface, and a side surface of a contact-area light emitting layer provided in the contact hole, among the light emitting layer, are wrapped by a fluorine-based protective layer.

In the contact hole, the cathode is connected to a metal layer connected to the auxiliary electrode.

The metal layer includes the same material as an anode provided at a lower end of the light emitting layer in each of the pixels.

A first fluorine-based protective layer is provided at the lower surface of the contact-area light emitting layer, a second fluorine-based protective layer is provided on the upper surface of the contact-area light emitting layer, and the side surface of the contact-area light emitting layer is wrapped by at least one of the first fluorine-based protective layer and the second fluorine-based protective layer.

the cathode is connected to a metal layer on the side surface of the contact-area light emitting layer, and the metal layer is connected to the auxiliary electrode.

The first fluorine-based protective layer is provided between the metal layer and the lower surface of the contact-area light emitting layer.

The metal layer includes the same material as the anode provided at a lower surface of the light emitting layer in each of the pixels.

The cathode provided on the side surface of the contact-area light emitting layer is covered by the metal layer.

The metal layer provided on the side surface of the contact-area light emitting layer is covered by the cathode.

An end of the cathode provided on the side surface of the contact-area light emitting layer is connected to the metal layer.

A pixel driving circuit layer including transistors which drive pixels is provided on the substrate, a planarization layer planarizing the driving circuit layer is provided on the pixel driving circuit layer, anodes included in the pixels are provided on the planarization layer, the anodes are covered by the light emitting layer, the auxiliary electrode is provided in the pixel driving circuit layer, and the contact hole passes through the planarization layer.

The auxiliary electrode is exposed in the contact hole.

The contact hole extends to at least one of insulation layers configuring the pixel driving circuit layer, and the auxiliary electrode is exposed in the contact hole.

A metal layer is provided on a sidewall of the contact hole, a first fluorine-based protective layer is provided on the metal layer, the contact-area light emitting layer is provided on the first fluorine-based protective layer, a second fluorine-based protective layer is provided on the contact-area light emitting layer, the cathode is provided on the second fluorine-based protective layer, and the metal layer is connected to the auxiliary electrode at a lower end of the contact hole.

The side surface of the contact-area light emitting layer provided at a lower end of the contact hole is wrapped by at least one of the first fluorine-based protective layer and the second fluorine-based protective layer.

The cathode is connected to the metal layer on the side surface.

The cathode provided on the side surface covers at least one of the first fluorine-based protective layer and the second fluorine-based protective layer provided on the side surface, and the metal layer provided on the side surface covers at least one of the first fluorine-based protective layer and the second fluorine-based protective layer provided on the side surface.

According to an embodiment of the present disclosure, when a cathode and an auxiliary electrode are connected in a contact hole by a laser process, a side surface of a contact-area light emitting layer provided in the contact hole can be covered by a fluorine-based protective layer. Accordingly, while the laser process is in progress and even after the laser process is performed, moisture cannot penetrate into the inside of the contact-area light emitting layer through the side surface of the contact-area light emitting layer.

The contact-area light emitting layer is connected to a light emitting layer provided on an anode. Therefore, if moisture penetration into the contact-area light emitting layer is prevented by the fluorine-based protective layer, moisture penetration from the outside into the light emitting layer can also be prevented.

Accordingly, the quality of a light emitting device and light emitting display apparatus can be improved.

Moreover, according to an embodiment of the present disclosure, moisture penetration into the light emitting layer can be prevented or reduced, and accordingly, the lifespan of the light emitting display apparatus can be extended, and a low-power light emitting display apparatus can be provided.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A light emitting display apparatus comprising:
a substrate including a display area and a non-display area;
a light emitting layer in a pixel in the display area;
a cathode on the light emitting layer;
an auxiliary electrode connected to the cathode through a contact hole in the pixel; and
a fluorine-based protective layer that covers an upper surface, a lower surface that is opposite the upper surface, and a side surface that is between the upper surface and the lower surface of a contact-area light emitting layer that is in the contact hole.

2. The light emitting display apparatus of claim 1, further comprising:
a metal layer in the contact hole, the metal layer in contact with the auxiliary electrode,
wherein the cathode is electrically connected to the auxiliary electrode via the metal layer.

3. The light emitting display apparatus of claim 2, wherein the metal layer includes a same material as an anode located at a lower surface of the light emitting layer in the pixel.

4. The light emitting display apparatus of claim 1, wherein the fluorine-based protective layer comprises:
a first fluorine-based protective layer covers the lower surface of the contact-area light emitting layer,
a second fluorine-based protective layer covers the upper surface of the contact-area light emitting layer,
wherein the side surface of the contact-area light emitting layer is covered by at least one of the first fluorine-based protective layer or the second fluorine-based protective layer.

5. The light emitting display apparatus of claim 4, further comprising:
a metal layer in the contact hole, the metal layer in contact with the auxiliary electrode,
wherein the cathode is in contact with the metal layer on the side surface of the contact-area light emitting layer.

6. The light emitting display apparatus of claim 5, wherein the first fluorine-based protective layer is between the metal layer and the lower surface of the contact-area light emitting layer.

7. The light emitting display apparatus of claim 5, wherein the metal layer includes a same material as an anode provided at a lower surface of the light emitting layer in the pixel.

8. The light emitting display apparatus of claim 5, wherein a portion of the cathode on the side surface of the contact-area light emitting layer is covered by a portion of the metal layer.

9. The light emitting display apparatus of claim 5, wherein a portion of the metal layer on the side surface of the contact-area light emitting layer is covered by a portion of the cathode.

10. The light emitting display apparatus of claim 5, wherein an end of the cathode on the side surface of the contact-area light emitting layer is in contact with the metal layer.

11. The light emitting display apparatus of claim 1, further comprising:
a pixel driving circuit layer including a transistor that drives the pixel and the auxiliary electrode,
a planarization layer on the pixel driving circuit layer and planarizing the pixel driving circuit layer, the contact hole through an entire thickness of the planarization layer; and
an anode included in the pixel, the anode on the planarization layer and covered by the light emitting layer.

12. The light emitting display apparatus of claim 11, wherein a portion of the auxiliary electrode is exposed in the contact hole.

13. The light emitting display apparatus of claim 11, wherein the contact hole extends to at least one of a plurality of insulation layers included in the pixel driving circuit layer, and a portion of the auxiliary electrode is exposed in the contact hole.

14. The light emitting display apparatus of claim 11, further comprising:
a metal layer on a sidewall of the contact hole,
wherein the fluorine-based protective layer comprises:
a first fluorine-based protective layer between the metal layer and the contact-area light emitting layer in the contact hole; and
a second fluorine-based protective layer between the cathode and the contact-area light emitting layer in the contact hole,
wherein the metal layer is connected to the auxiliary electrode at a lower end of the contact hole.

15. The light emitting display apparatus of claim 14, wherein the side surface of the contact-area light emitting layer at the lower end of the contact hole is covered by at least one of the first fluorine-based protective layer or the second fluorine-based protective layer.

16. The light emitting display apparatus of claim 15, wherein the cathode contacts the metal layer on the side surface.

17. The light emitting display apparatus of claim 15, wherein the cathode on the side surface covers at least a portion of one of the first fluorine-based protective layer or the second fluorine-based protective layer that is on the side surface, and a portion of the metal layer on the side surface covers at least a portion of one of the first fluorine-based protective layer or the second fluorine-based protective layer that is on the side surface.

18. A display device, comprising:
a substrate including a display area having a light emission area and a non-light emission area;
a transistor in the light emission area;
an auxiliary electrode in the non-light emission area;
a planarization layer on the transistor and the auxiliary electrode, the planarization layer including a contact hole through a portion of the planarization layer in the non-light emission area;
an anode electrode in the light emission area, the anode electrode connected to the transistor;
a light emission layer on the anode electrode in the light emission area, the light emission layer including a portion that extends into the contact hole that is in the non-light emission area;
a cathode electrode on the light emission layer in the light emission area and electrically connected to the auxiliary electrode, the cathode electrode including a portion that extends into the contact hole in the non-light emission area; and
a moisture blocking layer in the non-light emission area, the moisture blocking layer wrapping around the portion of the light emission layer in the contact hole.

19. The display device of claim 18, wherein the moisture blocking layer includes fluorine.

20. The display device of claim 18, wherein the moisture blocking layer includes a first portion that is in direct contact with a first surface of the portion of the light emission layer in the contact hole, a second portion that is direct contact with a second surface of the portion of the light emission layer that is spaced apart from the first surface, and a third portion that is in direct contact with a third surface of the portion of the light emission layer that is between the first surface and the second surface of the portion of the light emission layer that is in the contact hole.

21. The display device of claim 18, further comprising:
a metal layer in the contact hole in the non-light emission area, the metal layer in direct contact with the auxiliary electrode in the contact hole,
wherein the cathode electrode is in direct contact with the metal layer in the contact hole to electrically connect the cathode electrode and the auxiliary electrode.

22. The display device of claim 21, wherein a first portion of the moisture blocking layer is between the portion of the light emission layer and the metal layer in the contact hole, and a second portion of the moisture blocking layer is between the portion of the light emission layer and the portion of the cathode electrode in the contact hole.

23. The display device of claim 21, wherein an end of the portion of the cathode electrode that is on a side surface of the portion of the light emission layer in the contact hole is covered by an end of the metal layer.

24. The display device of claim 21, wherein an end of the portion of the metal layer that is on a side surface of the portion of the light emission layer in the contact hole is covered by an end of the cathode electrode.

25. The display device of claim 21, wherein an end of the portion of the cathode electrode contacts an upper surface of a portion of the metal layer that extends past an end of the portion of the light emission layer in the contact hole.

26. The display device of claim 21, wherein a portion of the auxiliary electrode in the contact hole is non-overlapped by the metal layer, the portion of the light emission layer in the contact hole, the moisture blocking layer, and the portion of the cathode electrode in the contact hole.

27. The display device of claim 18, wherein the display area includes a transmission area that is more transmissive of external light than the light emission area, and a first portion of the planarization layer that is in the light emission area is thicker than a second portion of the planarization layer that is in the transmission area.
